(19) United States
(12) Patent Application Publication
(10) Pub. No.: US 2009/0278537 A1
(43) Pub. Date: Nov. 12, 2009

(54) RADIO-FREQUENCY SURFACE COILS COMPRISING ON-BOARD DIGITAL RECEIVER CIRCUIT

(75) Inventor: Paul Royston Harvey, Best (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/305,528

(22) PCT Filed: Jun. 29, 2007
(86) PCT No.: PCT/IB2007/052529

§ 371 Date: Dec. 18, 2008

(30) Foreign Application Priority Data
Jun. 30, 2006 (EP) 06116404.2

(51) Int. Cl. G01R 33/48; G01R 33/44

(52) U.S. Cl. 324/309; 324/318

(57) ABSTRACT

A radio-frequency (RF) coil system that simplifies multi-nuclear magnetic resonance (MR) imaging is disclosed herein. The RF coil system comprises a transmitter coil (102) for transmitting an RF signal to excite a target region of a subject. The RF coil system also comprises an independent planar receiver coil assembly (110) for receiving an MR signal from at least a portion of the target region, the planar receiver coil assembly (110) being configured to include an on-board digital receiver circuit (112) for processing the received MR signal.

### FIELD OF THE INVENTION

This invention relates to magnetic resonance (MR) imaging and spectroscopy, and particularly to radio-frequency (RF) coils.

### BACKGROUND OF THE INVENTION

U.S. Pat. No. 6,946,840 discusses an RF array coil comprising a plurality of transmitter and receiver coils. However, using their RF array coil to perform multi-nuclear (MN) imaging could result in a complicated and expensive system, as much of the hardware will need to be duplicated to enable the transmitter to excite different nuclear species, as well as to enable the receiver to receive data from each different nuclear species. It is therefore desirable to have a simpler and cheaper implementation of an RF coil system that is capable of MN imaging. It is also desirable to have a simpler and cheaper method of MN imaging using the said RF coil system, as well as to have an MR system capable of performing MN imaging in a simpler and cheaper fashion utilizing the said RF coil system.

### SUMMARY OF THE INVENTION

Accordingly, an RF coil system that simplifies MN imaging is disclosed herein, the RF coil system comprising a transmitter coil for transmitting an RF signal to excite a target region, and a planar receiver coil assembly for receiving an MR signal from at least a portion of the target region, wherein the planar receiver coil assembly includes an on-board digital receiver circuit for processing the received magnetic resonance signal. A single transmitter coil reduces both the complexity and the cost involved in realizing MN imaging on the transmitter side, while including a digital receiver circuit on-board each receiver coil assembly does the same on the receiver side, as explained below. The term “on-board receiver circuit” indicates that the receiver circuit may be mounted on the circuit board holding the coil itself, or placed on a separate circuit board in close proximity to the receiver coil.

The operating frequency of a planar receiver coil assembly as disclosed herein is determined by its resonance frequency. The resonance frequency also determines the configuration of the on-board receiver circuit, for example the sampling or digitization frequency as well as the frequency of modulation and/or filtering. This operating frequency, which is thus defined almost entirely by the receiver coil assembly including the on-board digital receiver circuit, is therefore independent of the rest of the hardware on the MRI system. A planar receiver coil assembly tuned to a particular frequency or range of frequencies could connect directly to the same physical interface to the MR system, as another planar receiver coil assembly tuned to a different frequency or range of frequencies. Alternatively, a tunable planar receiver coil assembly initially tuned to a particular frequency or range of frequencies and connecting to the MR system via a particular physical interface could be retuned to a different frequency or range of frequencies and still connect to the MR system via the same physical interface. The remote MR system thus only has to support a digital coil data connection and is no longer frequency specific on the receive side. As a result, duplication of hardware is minimized, yielding a simpler and cheaper RF coil system capable of performing MN imaging.

Correspondingly, an MR system capable of performing MN imaging in a simpler and cheaper fashion utilizing the said RF coil system is also disclosed herein, the RF coil system comprising a transmitter coil for transmitting an RF signal to excite a target region, and a planar receiver coil assembly for receiving an MR signal from at least a portion of the target region, wherein the planar receiver coil assembly includes an on-board digital receiver circuit for processing the received magnetic resonance signal.

Furthermore, a simpler and cheaper method of MN imaging utilizing the said RF coil system is also disclosed herein, the method comprising transmitting an RF signal from a transmitter coil to excite a target region, receiving an MR signal from at least a portion of the target region using a planar receiver coil assembly, and processing the received magnetic resonance signal using a digital receiver circuit placed on-board the planar receiver coil assembly.

Furthermore, a computer program comprising instructions for switching such a radio-frequency coil system—comprising a transmitter coil and a planar receiver coil assembly—between transmit, receive and detune modes is also disclosed herein. The computer program comprises instructions to activate an active decoupling circuit to switch the planar receiver coil assembly from a receive mode to a detune mode when the transmitter coil is in operation, and to activate another active decoupling circuit to switch the transmitter coil from a transmit mode to a detune mode when the planar receiver coil assembly is in operation.

### BRIEF DESCRIPTION OF THE DRAWINGS

These and other aspects will be described in detail hereinafter by way of example on the basis of the following embodiments, with reference to the accompanying drawings, wherein:

FIG. 1a-1e show various embodiments of the disclosed RF coil system;

FIG. 2 schematically shows a possible circuit for a transmitter coil;

FIG. 3 schematically shows a possible circuit for a planar receiver coil assembly;

FIG. 4 shows an MR imaging or spectroscopy system that utilizes the disclosed RF coil system; and

FIG. 5 shows a method of acquiring MR imaging or spectroscopic data utilizing the disclosed RF coil system.

Corresponding reference numerals used in the various figures represent corresponding elements in the figures.

### DETAILED DESCRIPTION OF EMBODIMENTS

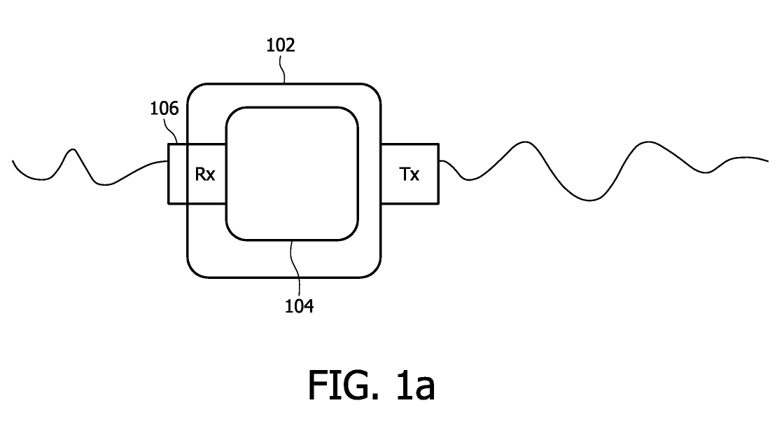

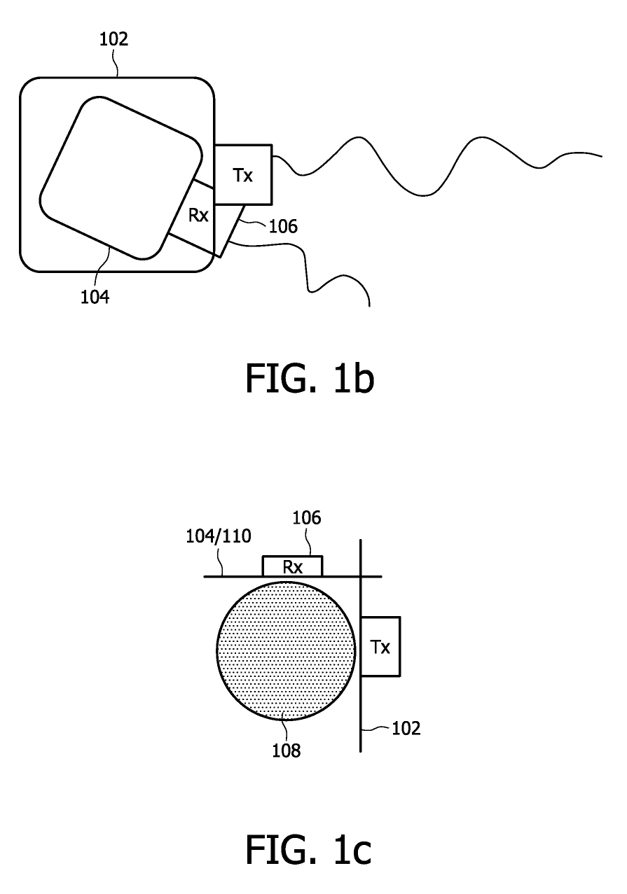

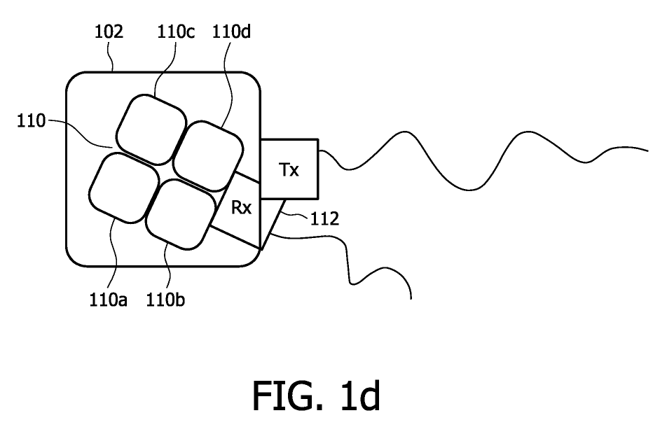

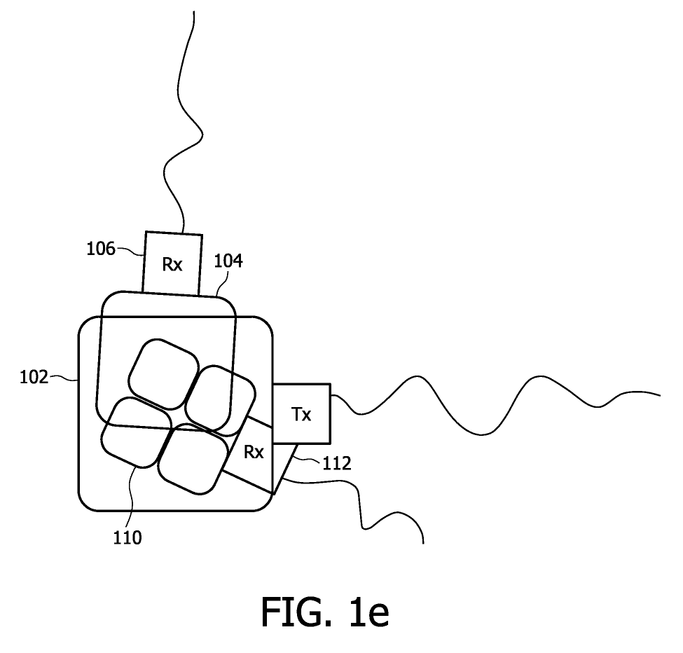

FIG. 1a-1e show various embodiments of an RF coil system comprising a transmitter coil 102 and one or more planar receiver coil assemblies 104, 110. Each planar receiver coil assembly 104, 110 includes an on-board digital receiver circuit 106, 112 capable of processing MR signals received by the respective planar receiver coil assembly 104, 110. In some embodiments the planar receiver coil assembly 104, 110 is configured to overlap the transmitter coil 102 (FIG. 1a, 1b, 1d, 1e), while in other embodiments the transmitter coil 102 and the planar receiver coil assembly 104, 110 are placed orthogonal to each other (FIG. 1c). In either the parallel or the orthogonal configuration, the planar receiver coil assembly 104, 110 is arranged to receive MR signal, for example, free induction decays or echoes, from at least a part of a region that has been excited by the transmitter coil 102.

The transmitter coil 102 and the planar receiver coil assembly 104, 110 are electrically independent of each other, and serve only one function each. In other words, the transmitter coil 102 is exclusively used for transmitting RF signals, while the planar receiver coil assembly 104, 110 is used exclusively to receive MR signals. During use, the coils are intended to be placed either concentric (i.e., fully overlapping), partially overlapping or orthogonal to each other. Various possible configurations of the receiver coil system comprising the transmitter coil 102 and the planar receiver coil assembly 104, 110 are shown in FIG. 1a-1e. FIG. 1c illustrates orthogonal placement of coils, for example on a leg or other part of a subject 108. FIG. 1e illustrates the use of multiple planar receiver coil assemblies 104, 110 with a single transmitter coil 102, while FIG. 1d shows an exemplary embodiment of a single transmitter coil 102 being used with a single receiver coil assembly 110 comprising multiple receiver coil elements or loops 110a, 110b, 110c, 110d. A single, large transmitter coil may be used with such a planar receiver coil assembly 110 comprising multiple loops, or alternatively with multiple planar receiver coil assemblies, thereby providing the capability for parallel imaging, including parallel MN imaging, without the complexity of realizing a combined multi-channel transmit and receive coil, both on system and coil level. Examples of parallel imaging techniques include the SENSE and the SMASH techniques. More information about the SENSE technique may be found in the article “SENSE: sensitivity encoding for fast MRI” by Pruessmann K P, Weiger M, Scheidegger M B, Boesiger P, Magnetic Resonance in Medicine, Volume 42, Issue 5, Pages 952-962 (1999). More information about the SMASH technique may be found in the article “Simultaneous acquisition of spatial harmonics (SMASH): fast imaging with radiofrequency coil arrays” by Sodickson D K, Manning W J, Magnetic Resonance in Medicine, Volume 38, Issue 4, Pages 591-603 (1997).

Separating transmit and receive functionality in this way also allows for greater flexibility with respect to realizing multi-channel, MN imaging. For example, by combining the use of a multiply-tuned transmitter coil with multiple planar receiver coil assemblies tuned to corresponding multiple frequencies, it is possible to realize multi-channel imaging of multiple nuclear species of interest. It is also possible to use a tunable planar receiver coil assembly wherein the planar receiver coil assembly initially tuned to a particular frequency is subsequently retuned to another frequency, thereby facilitating MN imaging in a sequential fashion. The tunable planar receiver coil assembly may be sequentially retuned to more than one additional frequency. Thus MN imaging may be either done separately for each of the nuclear species of interest or simultaneously for different nuclei.

As shown in FIG. 1a-1e, a single large transmitter coil 102 may be used in conjunction either with a single or with multiple planar receiver coil assemblies 104, 110. Using a larger transmitter coil 102 helps in exciting a particular region more uniformly, while using smaller receiver elements or coils or loops 104, 110a, 110b, 110c, 110d improves signal-to-noise ratio. While the transmitter coil 102 is illustrated as a planar or surface coil in FIG. 1a-1e, it should be clear that the transmitter coil 102 may also be a volume coil inside which the planar receiver coil assemblies 104, 110 may be placed. The planar receiver coil assembly 104 may be wound around a cylindrical former to form a pseudo-volume coil.

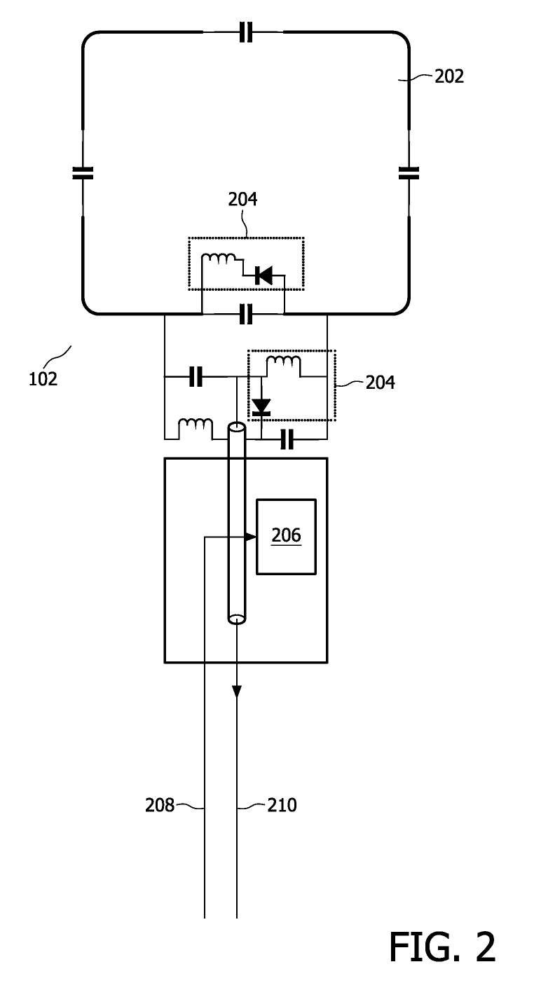

FIG. 2 shows a possible embodiment of a transmitter coil 102, which may be constructed from a conducting loop 202 which is made resonant at the frequency of a nucleus of interest, for example proton (¹H), carbon (¹³C), sodium (²³Na), etc. It is also possible to have the conducting loop 202, and therefore the transmitter coil 102, tuned to multiple resonance frequencies, so as to be able to excite multiple nuclei of interest. For instance, the transmitter coil 102 could be dual-tuned to ²³Na and ³¹P, or triple-tuned to ¹H, ¹³C and ³¹P, etc. With suitable modification, the transmitter coil 102 may even be designed to provide proton decoupling as well as excitation at the frequency of interest. The transmitter coil 102 may be detuned using active decoupling circuits 204, the detuning being controlled by the transmit/receive (T/R) control circuit 206. The control signal to switch the transmitter coil 102 from transmit mode to detune mode is transmitted via an electrical cable or wire 208, while the RF power is transmitted via an electrical cable or wire 210. It is also possible, with suitable modifications, to enable the transmitter coil 102 to operate in quadrature mode. Such suitable modifications are known in the art for both surface (or planar) as well as volume coils.

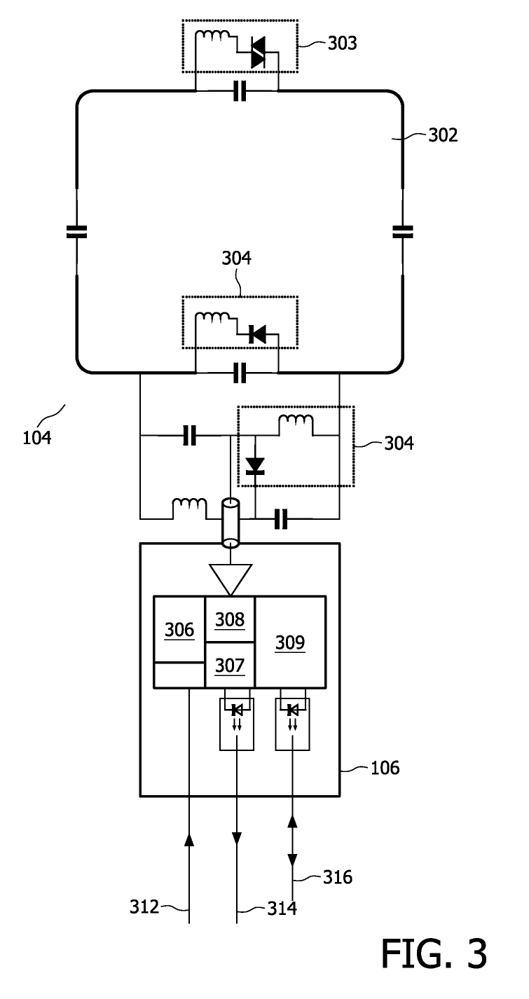

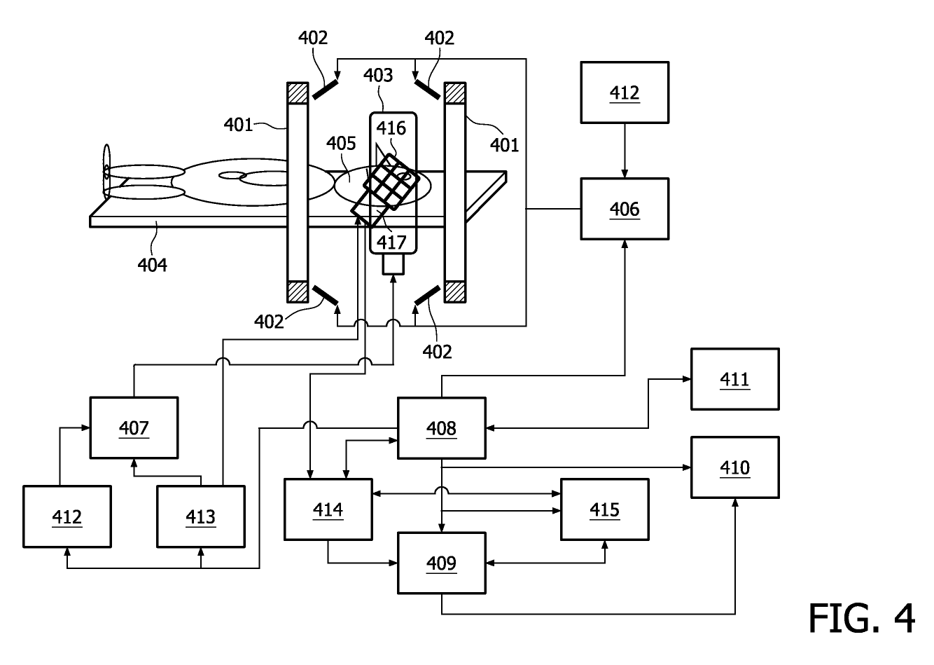

FIG. 3 shows a possible embodiment of an independent planar receiver coil assembly 104, 110, which may consist of a single loop 302 or multiple independent loops tuned to the frequency of a nucleus of interest. It is also possible to have the planar receiver coil assembly 104, 110 tuned to multiple frequencies, as mentioned in the case of the transmitter coil 102 above. A passive decoupling circuit 303 as well as active decoupling circuits 304 is provided for efficient decoupling of the planar receiver coil assembly 104, 110. In the case of a single loop receiver coil or antenna, the output is connected to a high-impedance pre-amplifier 306. The pre-amplifier output is connected to an analog-to-digital converter (ADC) 308. The pre-amplifier 306 and the ADC 308 may be located on the board containing the coil loop 302 or on a separate board in close proximity to the coil. The ADC 308 and pre-amplifier 306 also form part of a complete digital receiver circuit 106 that, together with the coil loop 302 and its associated capacitances and inductances that form the resonant circuit, determines the operational frequency of the planar receiver coil assembly 104, 110. Following analog-to-digital conversion by the ADC 308 and digital demodulation, the digital samples representing the received MR signal are converted to optical signals by an electro-optical converter 307 and transmitted to a remote reconstructor (409 in FIG. 4) via an optical fiber 314. Instead of optical data transfer, it is also possible to have a wireless transmitter (not shown) together with the digital receiver 106, which wirelessly transmits the digitized data to a wireless receiver outside the MR suite. A combination technique could also be used, wherein the data is transmitted via an optical fiber 316 (or wirelessly) to an optical (or wireless) receiver placed within the MR suite, and then conducted on conventional electrical cables from the optical (or wireless) receiver to the reconstructor placed outside the MR suite. Electrical power required for operation of the planar receiver coil assembly 104, 110 is supplied via an electrical cable or wire 312. Control signals are transmitted to, and received from, an onboard control unit 309 via an optical fiber 316.

Since both the transmitter coil 102 and the planar receiver coil assembly 104, 110 can overlap in space, it would be advantageous to provide adequate electrical decoupling between the planar receiver coil assembly 104, 110 and the transmitter coil 102, both during the transmit stage as well as the receive stage. In other words, the planar receiver coil assembly 104, 110 needs to be RF-invisible during RF-transmit, while the transmitter coil 102 should not affect the planar receiver coil assembly 104, 110 during RF-receive.

Adequate decoupling of the transmitter coil 102 and the planar receiver coil assembly 104, 110 may be achieved by combining active decoupling with passive decoupling elements, as shown in FIG. 2 and FIG. 3. Both the transmitter coil 102 and the planar receiver coil assembly 104 may contain decoupling circuits. These decoupling circuits, when activated, are intended to spoil the resonance of the respective coil loop, i.e., the transmitter coil loop 202 or the planar receiver coil loop 302, and thereby avoid unwanted coupling. When the transmitter coil 102 is activated, the planar receiver coil assembly 104 is in decoupling mode and thus is not resonant. Hence it does not have much influence on the transmitter coil 102. When the planar receiver coil assembly 104 is activated, the transmitter coil 102 is in decoupling mode and, by virtue of the fact that it is essentially an electrical open circuit, does not couple strongly with the planar receiver coil assembly 104. Thus, the decoupling circuits on both the transmitter coil 102 and the planar receiver coil assembly 104 help in reducing the coupling between the coils, irrespective of their relative placement.

The active decoupling elements 204, 304 contain a capacitor and inductor in parallel with a diode in series with the inductor. Together these components form a local parallel resonant circuit to the resonant circuit formed by the coil loop 202, 302 and associated capacitances. The inductance is chosen so that this parallel resonant circuit matches the resonant frequency of the coil loop 202, 302. When the coil loop 202, 302 is in resonant mode, the diode is reverse-biased using a controlled DC voltage so that the parallel resonant circuit is not at resonance and the capacitor contributes to the series resonance of the coil loop 202, 302. When the diode is forward biased (by switching the DC voltage to the opposite polarity), the capacitor and inductor become resonant and create a high impedance at the place where they are located. As a consequence of the high impedance, the coil loop 202, 302 is no longer resonant. The passive decoupling element is similar to the active element except that it contains two parallel reversed diodes. The diodes remain “open circuited”, i.e., non-conducting, until the transmitter coil, during transmit, induces sufficient voltage in the receive coil to forward-bias both diodes and complete the local parallel resonant circuit. Once again, when the diodes conduct, the local resonant circuit creates a high impedance at that point which breaks the resonance of the larger coil loop.

The additional passive decoupling elements 303 ensure adequate detuning of the planar receiver coil assembly 104, 110 and prevent a hazard in case of failure or mistiming of the active decoupling circuitry 204, 304. The electronics may include additional components to provide tuning and matching as well as active decoupling capability.

Active decoupling of the transmitter coil 102 is also required during receive mode of the planar receiver coil assembly 104, 110 in order to prevent coupling of noise into the planar receiver coil assembly 104, 110. During operation, the transmitter coil 102 is either transmitting RF signals or is in decoupling mode. It is switched between the two modes under control of the transmit/detune switch which may be located remotely from the planar receiver coil assembly 104, 110, on the MR system.

From the perspective of patient safety, the use of optical or wireless data transfer reduces the possibility of RF burns by preventing coupling between transmitter and receiver components. This is true for both planar surface coils and volume body coils.

FIG. 4 is a block diagram of an MR imaging system comprising an RF coil system as disclosed herein. The MR imaging system comprises a set of main coils 401, multiple gradient coils 402 connected to a gradient driver unit 406, and an RF coil system comprising a transmitter coil 403 connected to an RF coil driver unit 407. The function of the transmitter coil 403, which may be integrated into the magnet in the form of a body coil, or may be separate surface coils, is further controlled by a transmit/detune (T/D) switch 413. A planar receiver coil assembly 416 is used to acquire MR signals from at least a portion of a region excited by the transmitter coil 403, and the MR signals are processed by an on-board digital receiver circuit 417. The processed MR signals are transferred as optical signals from the on-board digital receiver 417 to an optical signal conversion unit 414. The multiple gradient coils 402 and the transmitter coil 403 are powered by a power supply unit 412. A transport system 404, for example a patient table, is used to position the subject 405, for example a patient, within the MR imaging system. A control unit 408 controls the operation of a reconstructor 409, a display unit 410, for example a monitor screen or a projector, a data storage unit 415, and a user input interface unit 411, for example, a keyboard, a mouse, a trackball, etc.

The main coils 401 generate a steady and uniform static magnetic field, for example, of field strength 1 T, 1.5 T or 3 T. The disclosed RF coil system is applicable to any other field strength as well. The main coils 401 are arranged in such a way that they typically enclose a tunnel-shaped examination space, into which a subject 405 may be introduced. Another common configuration comprises opposing pole faces with an air gap in between them into which the subject 405 may be introduced by using the transport system 404. To enable MR imaging, temporally variable magnetic field gradients superimposed on the static magnetic field are generated by the multiple gradient coils 402 in response to currents supplied by the gradient driver unit 406. The power supply unit 412, fitted with electronic gradient amplification circuits, supplies currents to the multiple gradient coils 402, as a result of which gradient pulses (also called gradient pulse waveforms) are generated. The control unit 408 controls the characteristics of the currents, notably their strength, duration and direction, flowing through the gradient coils to create the appropriate gradient waveforms. The transmitter coil 403 generates RF excitation pulses in the subject 405, while the planar receiver coil assembly 416 receives MR signals generated by the subject 405 in response to the RF excitation pulses. The RF coil driver unit 407 supplies current to the transmitter coil 403 to transmit the RF excitation pulses. The characteristics of the transmitted RF excitation pulses, notably their strength and duration, are controlled by the control unit 408. The transmitter coil 403 is operated in one of two modes, namely transmit and detune modes, by the control unit 408 via the T/D switch 413. The T/D switch 413 is provided with electronic circuitry that switches the transmitter coil 403 between the two modes, and prevents the transmitter coil 403 from coupling noise during signal acquisition by the planar receiver coil assembly 416. The T/D switch 413 also switches the planar receiver coil assembly 416 between two modes during operation, namely receive mode and detune or decoupling mode. The planar receiver coil assembly 416 is switched to decoupling mode during the transmit mode of the independent transmitter coil 403 and to receive mode during the decoupling mode of the transmitter coil 403. The switching between the two modes of both the transmitter coil 403 and the planar receiver coil assembly 416 is coordinated under software control of the MR system.

The RF transmitter coil 403 may be integrated into the magnet in the form of a body coil or as separate surface coils. The transmitter coil 403 may have different geometries, for example, a birdcage configuration or a simple loop configuration, etc. The control unit 408 is preferably in the form of a computer that includes a processor, for example a microprocessor. The control unit 408 controls, via the T/D switch 413, the application of RF pulse excitations and the reception of MR signals. User input interface devices 411 like a keyboard, mouse, touch-sensitive screen, trackball, etc., enable an operator to interact with the MR imaging system.

The optical signal conversion unit 414 converts optical signals into electrical signals. The converted electrical signals contain the actual information concerning the local spin densities in a region of interest of the subject 405 being imaged. The received signals are reconstructed by the reconstruction unit 409, and displayed on the display unit 410 as an MR image. It is alternatively possible to store the signal from the reconstruction unit 409 in a storage unit 415, while awaiting further processing.

Physical connections to the transmitter coil 403 include an RF coaxial cable for transmitting RF power and a power supply cable for providing a switchable voltage source for reverse/forward biasing of the active decoupling circuits (204 in FIG. 2). Physical connections to the planar receiver coil assembly 416 include one or more optical fibers (314, 316 in FIG. 3) for transferring digital data and control signals in optical form from the on-board receiver circuit 417 of the planar receiver coil assembly 416 to the reconstructor 409, a power supply cable (312 in FIG. 3) for providing power to the pre-amplifier, the digital receiver circuit 417 and decoupling switch circuitry.

The physical bulk of the transmitter coil 403 is minimized by locating the T/D switch 413 remotely from the transmitter coil 403 and connecting it via a flexible cable bunch (including the input cable for supplying the RF energy to the transmitter coil 403) and a suitable detachable plug/socket.

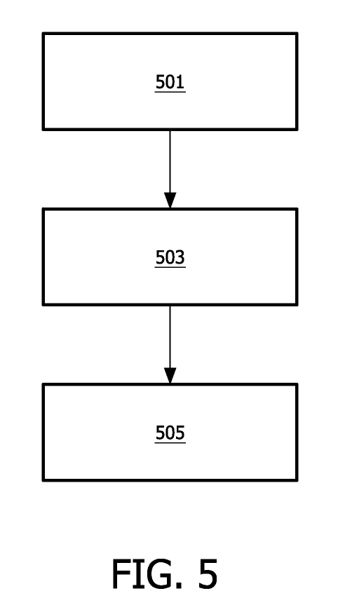

FIG. 5 shows a method of acquiring magnetic resonance imaging or spectroscopy data, using the RF coil system disclosed herein. In a transmitting step 501, a transmitter coil transmits an RF signal to a target region of a subject. In a receiving step 503, a planar receiver coil assembly is used to receive an MR signal from at least a portion of the target region, and in a processing step 505, a digital receiver circuit placed on-board the planar receiver coil assembly is used to process the received MR signal. The processing step 505 may involve one or more of the steps of pre-amplification, analog-to-digital conversion, conversion of electrical signal to optical signal, transmission of optical signal over an optical fiber cable, etc.

The computer program disclosed herein may reside on a computer readable medium, for example a CD-ROM, a DVD, a floppy disk, a memory stick, a magnetic tape, or any other tangible medium that is readable by a computer. The computer program may also be a downloadable program that is downloaded, or otherwise transferred to the computer, for example via the Internet. The computer program may be transferred to the computer via a transfer means such as an optical drive, a magnetic tape drive, a floppy drive, a USB or other computer port, an Ethernet port, etc.

It should be noted that the above-mentioned embodiments illustrate rather than limit the invention, and that those skilled in the art will be able to design many alternative embodiments without departing from the scope of the appended claims. A person skilled in the art may change the order of steps or perform steps concurrently using threading models, multi-processor systems or multiple processes without departing from the disclosed concepts. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed method can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

1. A radio-frequency coil system for magnetic resonance imaging or spectroscopy, comprising:
a transmitter coil for transmitting a radio-frequency signal to excite a target region; and
a planar receiver coil assembly for receiving a magnetic resonance signal from at least a portion of the target region, wherein the planar receiver coil assembly includes an on-board digital receiver circuit for processing the received magnetic resonance signal.

2. The radio-frequency coil system of claim 1, wherein the planar receiver coil assembly is tunable to one or more frequencies.

3. The radio-frequency coil system of claim 1, including multiple planar receiver coil assemblies.

4. The radio-frequency coil system of claim 1, wherein the transmitter coil is a planar coil, and wherein the planar receiver coil assembly is positioned in a plane parallel to the plane of the transmitter coil.

5. The radio-frequency coil system of claim 1, wherein the transmitter coil is a planar coil, and wherein the planar receiver coil assembly is positioned in a plane orthogonal to the plane of the transmitter coil.

6. The radio-frequency coil system of claim 1, wherein the transmitter coil is configured to transmit the radio-frequency signal at multiple frequencies.

7. The radio-frequency coil system of claims 1, wherein the one or more planar receiver coil assemblies are adapted to receive the magnetic resonance signal at multiple frequencies.

8. A magnetic resonance imaging or spectroscopy system including a radio-frequency coil system comprising:
a transmitter coil for transmitting a radio-frequency signal to excite a target region; and
a planar receiver coil assembly for receiving a magnetic resonance signal from at least a portion of the target region, wherein the planar receiver coil assembly includes an on-board digital receiver circuit for processing the received magnetic resonance signal.

9. A method of acquiring magnetic resonance imaging or spectroscopy data, comprising:
transmitting a radio-frequency signal from a transmitter coil to excite a target region;
receiving a magnetic resonance signal from at least a portion of the target region using a planar receiver coil assembly; and
processing the received magnetic resonance signal using a digital receiver circuit placed on-board the planar receiver coil assembly.

10. A computer program for a radio-frequency coil system comprising:
a transmitter coil including a first active decoupling circuit; and
a planar receiver coil assembly including an on-board digital receiver circuit and a second active decoupling circuit;
wherein the computer program comprises instructions:
to activate the first active decoupling circuit to switch the transmitter coil from a transmit mode to a detune mode when the planar receiver coil assembly is in operation; or
to activate the second active decoupling circuit to switch the planar receiver coil assembly from a receive mode to a detune mode when the transmitter coil is in operation;
when the computer program is run on a computer.
